(19) United States
(12) Patent Application Publication
(10) Pub. No.: US 2025/0391457 A1
(43) Pub. Date: Dec. 25, 2025

(54) APPARATUSES AND METHODS FOR RESETTING COUNTER BITS DURING SELF-REFRESH OF MEMORY DEVICES

(71) Applicant: Micron Technology, Inc., Boise, ID (US)

(72) Inventors: Yuan He, Boise, ID (US); Wenlun Zhang, Tokyo (JP)

(73) Assignee: Micron Technology, Inc., Boise, ID (US)

(21) Appl. No.: 19/237,726

(22) Filed: Jun. 13, 2025

Related U.S. Application Data
(60) Provisional application No. 63/662,247, filed on Jun. 20, 2024.

(51) Int. Cl. G11C 11/403

(52) U.S. Cl. CPC G11C 11/403

(57) ABSTRACT

Apparatuses, systems, and methods for clearing or resetting an access count value during a self-refresh mode. Various patterns of access to a row, sometimes called an aggressor row, may cause an increased rate of information decay in memory cells along nearby word lines, at which point they may be referred to as victim rows. Aggressor rows are identified by their access counts so that victim rows may be refreshed to prevent information decay. A memory may be placed in a self-refresh mode. During the self-refresh mode, a counter reset detector circuit clears or resets the access count value stored in counter memory cells associated with each address as it is refreshed. In this manner, potential victim rows are refreshed during the self-refresh mode along with would-be aggressor rows and fewer targeted refreshes may be issued.

### CROSS-REFERENCE TO RELATED APPLICATIONS

This application claims the filing benefit of U.S. Provisional Application No. 63/662,247, filed Jun. 20, 2024. This application is incorporated by reference herein in its entirety and for all purposes.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal, for example as a charge on a capacitive element. During an access operation, an access command may be received along with address information which specifies which memory cells should be accessed.

As memory components have decreased in size, the density of memory cells has greatly increased. Repeated access to a particular memory cell or group of memory cells, often referred to as a “row hammer,” may cause an increased rate of data degradation in nearby memory cells. Memory cells affected by the row hammer effect may be identified by keeping an access count for a particular memory cell or group of memory cells. The identified memory cells may then be refreshed as part of a targeted refresh operation or as part of other refresh operations. It may be useful to adjust access counts to help prevent unnecessary refresh operations.

### BRIEF DESCRIPTION OF DRAWINGS

FIG. 1 is a block diagram of a semiconductor device according to some embodiments of the disclosure.

FIG. 2 is a block diagram of a refresh control circuit according to some embodiments of the present disclosure.

FIG. 3 is a block diagram of a counter reset detector circuit according to some embodiments of the present disclosure.

FIG. 4 is a timing chart of clear operations according to some embodiments of the present disclosure.

FIG. 5 is a timing chart of clear operations where the refresh address wraps back around to an initial value according to some embodiments of the present disclosure.

FIG. 6 is a block diagram according to some embodiments of the present disclosure.

FIG. 7 is a block diagram according to some embodiments of the present disclosure.

FIG. 8 is a flow chart of a method of clearing access count values during a self-refresh mode according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Information in a memory array may be accessed by one or more access operations, such as read or write operations. During an example access operation a word line may be activated based on a row address and then selected memory cells along that active word line may have their information read from or written to based on which bit lines are accessed. Which bit lines are accessed may be based on a column address. The memory array may be refreshed on a row-by-row basis, such as part of an auto-refresh and/or self-refresh mode, where the memory cells along each row are refreshed periodically. The speed at which the rows are refreshed, or the maximum time any given row will go between refreshes, may be determined based on an expected rate of information decay.

Various patterns of access to a row, sometimes called an aggressor row, may cause an increased rate of information decay in memory cells along nearby word lines, at which point they may be referred to as victim rows. For example, a “row hammer” may involve repeated accesses to the aggressor row which may increase a rate of decay in adjacent rows and/or in rows which are further away. Accordingly, it may be important to track a number of accesses to each row to determine if they are aggressors, such that the victim rows can be identified and refreshed as part of a refresh operation, such as a targeted refresh operation.

Some memories may use a per row activation counter (PRAC) scheme, where each word line has an associated count value used to determine how many times that word line has been accessed. When the row is accessed the count may be changed, such as incremented, by a counter circuit and compared to a mitigation threshold by a comparator. If the count crosses the mitigation threshold, then the address may be added to an aggressor queue and during targeted refresh operations, the addresses in the queue are used to generate refresh addresses. For example, the refresh addresses may correspond to the word lines adjacent to the word line associated with the address in the aggressor queue because the adjacent word lines may be victim rows. The victim rows may be identified as one word line on either side of the aggressor row, two word lines on either side, or any number of word lines adjacent to the aggressor row.

There may be times when the memory device enters a self-refresh mode, such as when the memory device is idle, and the memory device refreshes addresses according to an internal scheme, such as row-by-row. During the self-refresh mode, the addresses may be refreshed regardless of the access count associated with the address, for example row-by-row and thus, potentially refreshing victim rows adjacent to would-be aggressor rows and eliminating the need for a targeted refresh. It may be desirable then to clear or reset the access count associated with an address refreshed during the self-refresh mode because any potential victim rows have also been refreshed and targeted refreshes may no longer be needed.

The present disclosure is drawn to apparatuses, systems, and methods for clearing or resetting an access count value during a self-refresh mode. A memory may be placed in a self-refresh mode. During the self-refresh mode, a counter reset detector circuit clears or resets the access count value stored in counter memory cells associated with each address as it is refreshed. In this manner, fewer targeted refreshes may be issued because potential victim rows are refreshed during the self-refresh mode along with would-be aggressor rows.

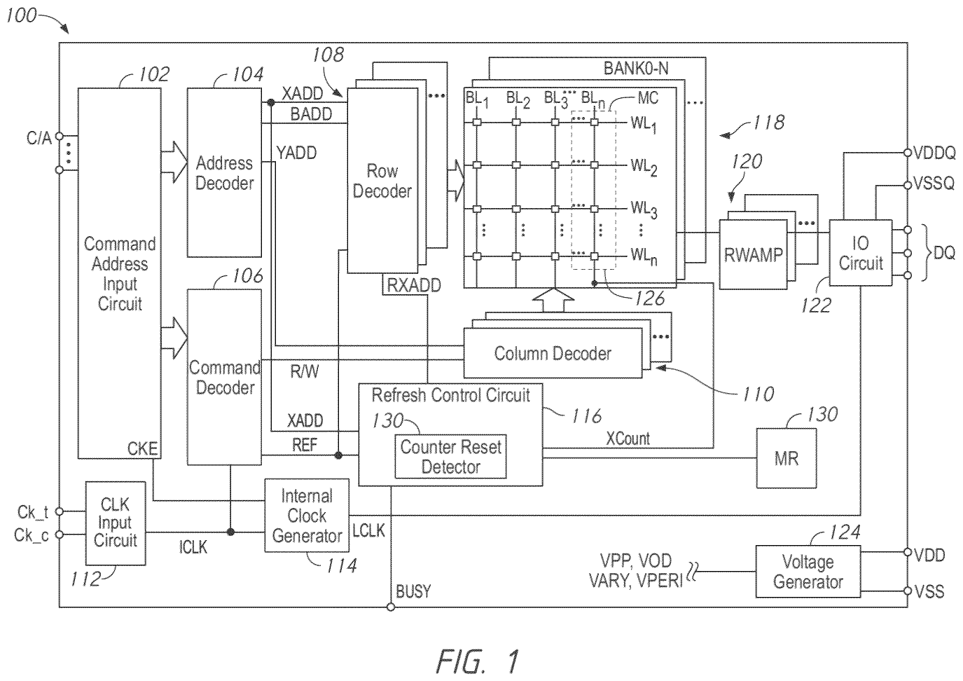

FIG. 1 is a block diagram of a semiconductor device according to at least one embodiment of the disclosure. The semiconductor device 100 may be a semiconductor memory device, such as a dynamic random access memory (DRAM) device integrated on a single semiconductor chip.

The semiconductor device 100 includes a memory array 118. The memory array 118 is shown as including a plurality of memory banks. In the embodiment of FIG. 1, the memory array 118 is shown as including memory banks BANK0-BANKN. The number of memory banks in the memory array 118 may, for example, be 4, 8, 16, or 32. More or fewer banks may be included in the memory array 118 of other embodiments. The memory banks may be further organized into memory bank groups (not shown in FIG. 1). For example, a device with thirty-two memory banks may be further organized into eight memory bank groups, with each bank group including four memory banks. Each memory bank includes a plurality of word lines WL (rows), a plurality of bit lines BL (columns), and a plurality of memory cells MC arranged at intersections of the plurality of word lines WL and the plurality of bit lines BL.

The selection of a word line WL is performed by a row decoder 108 and the selection of bit lines BL is performed by a column decoder 110. In the embodiment of FIG. 1, the row decoder 108 includes a respective row decoder for each memory bank and the column decoder 110 includes a respective column decoder for each memory bank.

Some of the memory cells may be set aside as counter memory cells 126. The counter memory cells may store access count values XCount, each of which is associated with one of the word lines. The access count value XCount may represent a number of times the associated word lines has been accessed. Each access count value XCount may be stored in counter memory cells 126 along the word line that the count value is associated with. The access count value XCount may be stored as a binary number, with each bit stored in a memory cell along the word line. For the sake of clarity, a single bit line of counter memory cells 126 is shown in FIG. 1. However, any number of counter memory cells 126 may be used along the word line. For example, the number of counter memory cells 126 along each word line may be based on a number of bits of the access count value XCount.

The semiconductor device 100 may employ a plurality of external terminals that include command and address (C/A) terminals coupled to a command and address bus to receive commands and addresses, clock terminals to receive clocks Ck_t and Ck_c, data terminals DQ to provide data, and power supply terminals to receive power supply potentials VDD, VSS, VDDQ, and VSSQ.

The clock terminals are supplied with external clocks Ck_t and Ck_c that are provided to an input circuit 112. The external clocks may be complementary. The input circuit 112 generates an internal clock ICLK based on the Ck_t and Ck_c clocks. The ICLK clock is provided to the command decoder 110 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include access commands for accessing the memory, such as read commands for performing read operations and write commands for performing write operations, refresh command for performing refresh operations, mode register read and write commands for setting modes in a mode register, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and provide a column command signal to select a bit line.

The device 100 may receive an access command, such as a read command. When a read command is received, a bank address BADD and a column address YADD are timely supplied with the read command, read data is read from activated memory cells of row address XADD in the memory array 118 corresponding to the column address YADD. The read command is received by the command decoder 106, which provides internal commands so that read data from the memory array 118 is provided to the read/write amplifiers 120. The read data is output to outside from the data terminals DQ via the input/output circuit 122. The access count value XCount stored counter memory cells 126 of the row associated with the row address XADD are read to the refresh control circuit 116, and an updated value of the access count is written back to the counter memory cells 126 of the row XADD.

The device 100 may receive an access command, such as a write command. When the write command is received, a bank address BADD and a column address YADD are timely supplied with the write command, write data supplied to the data terminals DQ is written to activated memory cells of row address XADD in the memory array 118 corresponding to the column address YADD. The write command is received by the command decoder 106, which provides internal commands so that the write data is received by data receivers in the input/output circuit 122. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cells MC. Similar to the read operation described above, the access count value XCount stored in counter memory cells 126 of the row associated with the row address XADD are read to the refresh control circuit 116, and an updated value of the access count is written back to the counter memory cells 126 of the row XADD.

The device 100 may also receive commands causing it to carry out refresh operations. For example, responsive to a refresh command, the command decoder 106 may provide refresh signals such as REF, RFM or combinations thereof. Responsive to a refresh command received from the controller, the refresh control circuit 116 performs one or more normal refresh operations, one or more targeted refresh operations, or combinations thereof. Responsive to an RFM command received from the controller, the refresh control circuit 116 performs one or more targeted refresh operations. The device 100 may also enter a self-refresh mode where the refresh signal is generated internally. For example, in some embodiments the device 100 may enter a self-refresh mode responsive to the device 100 entering an IDLE state.

The refresh signal REF may be a pulse signal which is activated when the command decoder 106 receives a signal which indicates a refresh command. In some embodiments, the refresh command may be externally issued to the memory device 100. In some embodiments, the refresh command may be periodically generated by a component of the device, for example as part of a self-refresh mode. In some embodiments, when an external signal indicates a self-refresh mode entry command, the refresh signal REF may also be activated. The refresh signal REF may be activated once immediately after command input, and thereafter may be cyclically activated at desired internal timing. Thus, refresh operations may continue automatically during self-refresh. A self-refresh exit command may cause the automatic activation of the refresh signal REF to stop and the memory device 100 to exit self-refresh mode.

The refresh command REF is supplied to the refresh control circuit 116. The refresh control circuit 116 supplies a refresh row address RXADD to the row decoder 108, which refreshes a word line WL identified by the refresh row address RXADD. The refresh control circuit 116 may include a counter reset detector circuit 130. The counter reset detector circuit 130 may reset, or clear, the access count value XCount from the counter memory cells 126 associated with the rows refreshed while the device 100 is in a self-refresh mode.

The power supply terminals are supplied with power supply potentials VDD and VSS. The power supply potentials VDD and VSS are supplied to an internal voltage generator circuit 124. The internal voltage generator circuit 124 generates various internal potentials VPP, VARY, VPERI, and the like based on the power supply potentials VDD and VSS supplied to the power supply terminals. The internal potential VPP is mainly used in the row decoder 108, the internal potentials VARY are mainly used in the sense amplifiers SAMP (not shown) included in the memory array 118, and the internal potential VPERI is used in many peripheral circuit blocks. The power supply terminals are also supplied with power supply potentials VDDQ and VSSQ. The power supply potentials VDDQ and VSSQ are supplied to the input/output circuit 122.

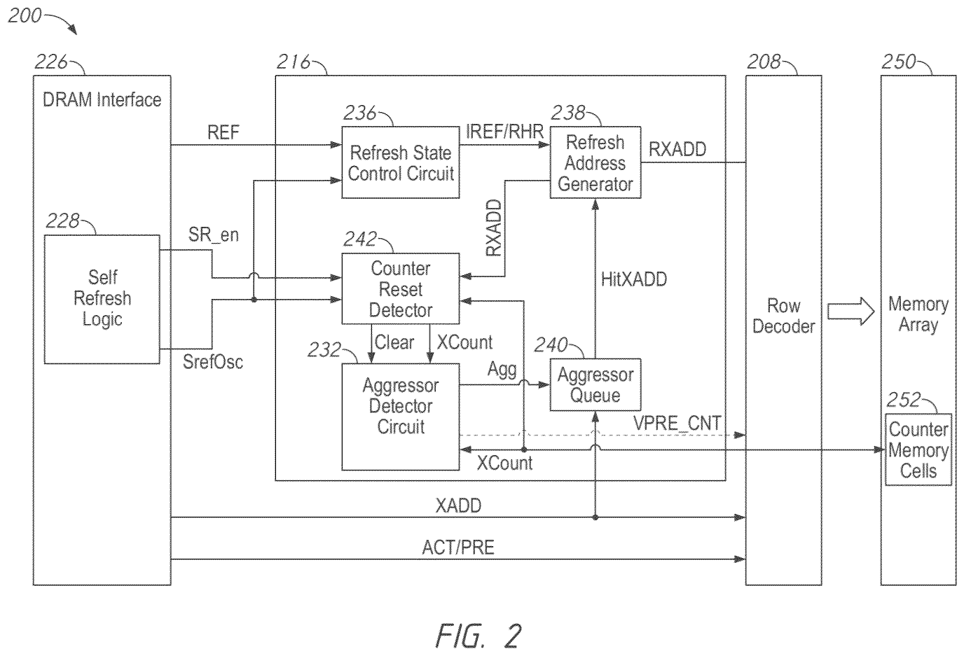

FIG. 2 is a block diagram of a refresh control circuit according to some embodiments of the present disclosure. The memory 200 may, in some embodiments, implement a portion of a memory device such as 100 of FIG. 1. The memory 200 shows certain components and signals which are used in refresh operations. The memory 200 includes a refresh control circuit 216 which may, in some embodiments implement the refresh control circuit 116 of FIG. 1. Also shown in FIG. 2 is a row decoder 208 (e.g., 108 of FIG. 1), a memory array 250 (e.g., 118 of FIG. 1) and a DRAM interface 226, which represents other components of the memory, such as the command decoder (e.g., 106 of FIG. 1) and address decoder (e.g., 104 of FIG. 1). The DRAM interface 226 is shown as including a self-refresh logic circuit 228.

The refresh control circuit 216 includes a refresh state control circuit 236 which receives the refresh signal REF from the interface 226 and performs normal and/or targeted refresh operations by issuing internal refresh signal IREF and/or targeted refresh signal RHR. Responsive to IREF and/or RHR, a refresh address generator 238 of the refresh control circuit 216 provides a refresh address RXADD. The refresh control circuit 216 also includes an aggressor detector circuit 232 which determines if an accessed row address XADD is an aggressor or not and a targeted refresh queue 240 which stores the identified aggressor addresses. When the refresh state control circuit 236 calls for a targeted refresh operation, the refresh address generator 238 generates the refresh address RXADD based on an aggressor address HitXADD from the queue 240.

The DRAM interface 226 represents various components of the memory which send and receive signals and addresses to the refresh control circuit 216 and row decoder 208. The signals may be based on commands and/or addresses received from outside the memory, such as from a controller, and/or may be internally generated signals. As part of access operations, the DRAM interface 226 provides a row address XADD along with an activation signal ACT. Responsive to the signal ACT, the row decoder 208 activates the word line of the memory array 250 associated with XADD. At the end of the access operation, the DRAM interface provides a pre-charge command PRE, and responsive to that the active word line is pre-charged (e.g, deactivated or closed). As part of refresh operations, the DRAM interface provides a refresh signal REF, which may be based on a refresh command received from a controller. Responsive to the refresh signal REF, the refresh control circuit 216 performs one or more refresh operations.

The DRAM interface 226 includes a self-refresh logic circuit 228. The self-refresh logic circuit 228 may provide a self-refresh enable signal SR_en and a self-refresh oscillator signal SrefOsc responsive to the memory device 300 being in self-refresh mode. Responsive to the self-refresh oscillator signal SrefOsc, the refresh state control circuit 236 may issue one or more internal refresh signals IREF to the refresh address generator 238. The internal refresh signal IREF may also be issued by the refresh state control circuit 236 to perform one or more normal refresh operations responsive to a refresh signal REF.

The refresh address generator circuit 238 provides a refresh address RXADD which indicates which word line or word lines should be refreshed as part of a refresh operation. As part of a normal refresh operation IREF may be active but not RHR. During a normal refresh, the refresh address generator circuit 238 generates the refresh address RXADD based on sequence logic. For example, the refresh address generator circuit 238 may include a counter circuit which generates a new normal refresh address based on a previous normal refresh address. In an example implementation, each normal refresh address may be generated by incrementing the previous normal refresh address. Responsive to the refresh address RXADD and the refresh signal IREF, the row decoder 208 refreshes one or more word lines associated with the refresh address RXADD. In some embodiments, the normal refresh address may be associated with multiple word lines. For example, during a normal refresh operation the refresh address RXADD may be truncated, and all the word lines associated with that truncated portion may be refreshed in common.

As part of a targeted refresh operation both IREF and RHR may be active and the refresh address generator 238 generates the refresh address RXADD based on an identified aggressor address HitXADD provided by the targeted refresh queue 240. The refresh address generator 238 may generate multiple refresh addresses based on a single aggressor address HitXADD. For example, the refresh address generator 238 may generate a first refresh address associated with a first word line adjacent to the word line associated with HitXADD and a second refresh address associated with a second word line adjacent to the word line associated with HitXADD. For ease of explanation, the word lines physically adjacent to a word line of address X will generally be referred to as being associated with row addresses X−1 and X+1. Other example embodiments may use other methods of assigning row address values to word lines. Accordingly, when an address HitXADD in the aggressor queue 240 is refreshed, the refresh address generator may generate RXADD=HitXADD−1 and RXADD=HitXADD+1. Responsive to the refresh address RXADD and the refresh signal IREF, the word line associated with RXADD is refreshed by the row decoder 208.

The refresh control circuit 216 includes an aggressor detector circuit 232 which determines if a row address XADD should be added to the targeted refresh queue 340 or not. In other words, the aggressor detector circuit 232 may determine if the row address XADD is an aggressor address. When the current row address is determined to be an aggressor, the aggressor detector circuit provides an aggressor signal Agg. The aggressor detector circuit 232 may use various criteria to determine if the address is an aggressor. For example, per-row activity tracking (PRAC) may be used.

The targeted refresh queue 240 includes a register with one or more slots, each of which may store an address. Responsive to the signal Agg, the targeted refresh queue 240 stores the current row address XADD in an empty one of the slots. Responsive to a targeted refresh operation (e.g., the signal RHR), an address in the queue 240 is provided as HitXADD and removed from the queue 240.

The memory array 250 includes a number of a counter memory cells 252 (e.g., 126 of FIG. 1) which store a number of access count values XCount each associated with a word line of the memory. For example, each word line may include a set of counter memory cells 252 (e.g., 126 of FIG. 1) which store that word line's access count value XCount as a binary number. When a word line is accessed, its access count value XCount is read out to the aggressor detector circuit 232. The aggressor detector circuit 232 updates the access count value XCount, for example by incrementing it, and compares the updated count to a threshold. If the count has not crossed the threshold, then the updated count value is written back to the counter memory cells 252 (e.g., 126 of FIG. 1). If the count has crossed the threshold, for example is equal to or greater than the threshold, then the aggressor detector circuit 232 provides an aggressor signal Agg, and resets or clears the count value. For example, the aggressor detector circuit 232 may reset the access count value XCount to an initial value such as 0.

The aggressor detector circuit 232 may also reset the access count values associated with an accessed or refreshed address responsive to a clear signal Clear from a counter reset detector circuit 242. In some embodiments, the clear signal Clear may be a flag that is enabled, or set to high, to initiate clear operations and disabled, or set to low, to end clear operations. In some embodiments, the aggressor detector circuit 232 may reset or clear the counter memory cells 252 (e.g., 126 of FIG. 1) of a refresh row address RXADD by writing a reset value, such as zero, to them responsive to the clear flag being enabled. In some embodiments, the aggressor detector circuit 232 may reset or clear the counter memory cells 252 (e.g., 126 of FIG. 1) by issuing a counter cell pre-charge value VPRE_CNT to the row decoder 208 (e.g., 108 of FIG. 1) that controls the pre-charge value of the sense amplifier(s) associated with the counter memory cells 252 (e.g., 126 of FIG. 1) responsive to the clear flag being enabled.

The refresh control circuit 216 includes the counter reset detector circuit 242. The counter reset detector circuit 242 is configured to clear, or reset, access count values associated with row addresses refreshed during self-refresh operations. The counter reset detector circuit 242 receives the self-refresh oscillator signal SrefOsc and the self-refresh enable signal SR_en from the self-refresh logic circuit 228. Responsive to receiving the self-refresh oscillator signal SrefOsc and the self-refresh enable signal SR_en being enabled, the counter reset detector circuit 242 may enable a clear flag Clear. For example, the clear flag Clear may be transmitted to an aggressor detector circuit 232 to cause the aggressor detector circuit 232 to clear, or reset, the access count value XCount stored in counter memory cells associated with a refresh row address RXADD on which refresh operations are occurring during self-refresh mode. In some embodiments, the counter reset detector circuit 242 may enable the clear flag Clear after a number of row addresses RXADD have been refreshed. For example, the counter reset detector circuit 242 may enable the clear flag Clear after one row address RXADD is refreshed during self-refresh mode. The clear flag Clear may not be enabled with the first row address RXADD to be refreshed because adjacent word lines, for example associated with prior row addresses such as RXADD−1, may be potential victim rows. If the first row address RXADD is a would-be aggressor row and its access count value is cleared, the would-be aggressor row can no longer be identified as an aggressor row and some of the potential victim rows may not receive a targeted refresh creating a risk that information stored in the memory cells along the victim rows may be lost.

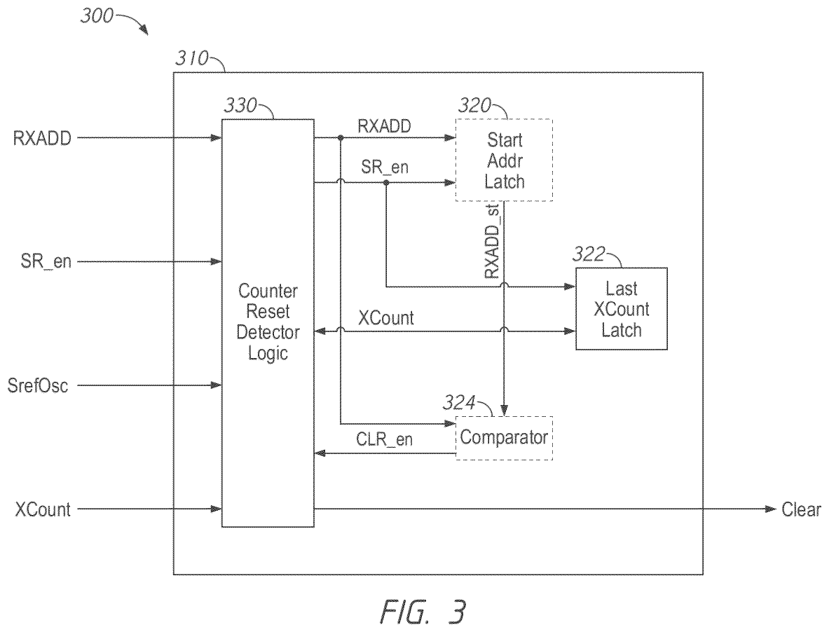

FIG. 3 is a block diagram of a counter reset detector circuit according to some embodiments of the present disclosure. The counter reset detector circuit 300 may, in some embodiments, implement a counter reset detector circuit such as 130 of FIG. 1 and/or 242 of FIG. 2. The counter reset detector circuit 300 shows certain components and signals which are used in clear operations.

The counter reset detector circuit 300 includes a counter reset detector logic circuit 330 which receives a self-refresh enable signal SR_en (e.g., the self-refresh enable signal is enabled) and a self-refresh oscillator signal SrefOsc from a self-refresh logic circuit such as 228 of FIG. 2. Responsive to the self-refresh enable signal SR_en and the self-refresh oscillator signal SrefOsc, the counter reset detector logic circuit 330 may perform clear operations. For example, the clear operations may clear or reset a count value associated with a row address RXADD refreshed during a refresh operation, such as XCount of FIGS. 1-2. In some embodiments, the refresh operation may be a self-refresh operation. Clear operations may be initiated by the counter reset detector circuit 330 enabling and providing a clear flag Clear, for example to an aggressor detector circuit (e.g., 232 of FIG. 2).

The counter reset detector circuit 300 includes a last XCount latch 322. The last XCount latch 322 receives the self-refresh enable signal SR_en and an access count value XCount from the counter reset detector logic circuit 330. Responsive to receiving the self-refresh enable signal SR_en and the access count value XCount, the last XCount latch 322 stores an access count XCount associated with the refresh row address RXADD being refreshed before that count value is reset. The value stored in the last XCount latch 322 will update with the refresh row address RXADD throughout the refresh operation to store the access count associated with the most recent row address to be refreshed. When the clear operation ends, the access count value stored in the last XCount latch 322 will be written back to the counter memory cells (e.g., 126 of FIG. 1 and/or 252 of FIG. 2) associated with the last row address to be refreshed. In some embodiments, the last XCount latch 322 may transmit the stored access count value to the counter reset detector logic circuit 330 to be written back to the counter memory cells (e.g., 126 of FIG. 1 and/or 252 of FIG. 2). The last access count XCount stored in the last XCount latch 322 is rewritten back to the counter memory cells (e.g., 126 of FIG. 1 and/or 252 of FIG. 2) of the last refresh row address RXADD to be refreshed because the last refresh row address RXADD may be identified as an aggressor row and the next row address RXADD+1, which was not refreshed during the self-refresh mode, may require a targeted refresh.

In some embodiments, the counter reset detector circuit 300 may include a starting address latch 320. For example, the starting address latch 320 may be a flip-flop. The starting address latch 320 may receive the self-refresh enable signal SR_en and a refresh row address RXADD from the counter reset detector logic circuit 330. Responsive to the self-refresh enable signal SR_en being enabled and receiving the refresh row address RXADD, the starting address latch 320 may store the refresh row address RXADD, for example for the duration of the clear operation. In some embodiments, the refresh row address RXADD may be associated with a row address on which refresh operations are being performed when the clear operation begins. In some embodiments, the counter reset detector logic circuit 330 may provide a refresh row address RXADD to the starting address latch 320 that is a row address other than the first row address to be refreshed. For example, the counter reset detector logic circuit 330 may provide the refresh row address RXADD to the starting address latch 320 that is a second row address to be refreshed by the memory (e.g., 100 of FIG. 1 and/or 200 of FIG. 2).

In some embodiments, the counter reset detector circuit 300 may include a comparator circuit 324. The comparator circuit 324 may receive the refresh row address RXADD and a stored starting address RXADD_st from the starting address latch 320. The refresh row address RXADD may indicate the row address currently being refreshed and the stored starting row address RXADD_st may represent the row address being refreshed when the clear operation began and the row address that is stored in the starting address latch 320. The comparator circuit 324 may compare, such as with an XOR gate, the refresh row address RXADD and the stored starting row address RXADD_st to determine whether the clear operation should continue. For example, if the stored starting row address RXADD_st is the same as the refresh row address RXADD, the access count value XCount associated with that row address has been cleared and the comparator circuit 324 may indicate to the counter reset detector logic 330 that the clear operation may be discontinued. The comparator circuit 324 may do this by transmitting a clear enable signal CLR_en to the counter reset detector logic circuit 330. If the refresh row address RXADD is not the same as the stored starting row address RXADD_st, then the comparator circuit 324 may indicate to the counter reset detector logic circuit 330 to continue clear operations. In other words, if the refresh operation such as a self-refresh operation, continues long enough to cycle through all row addresses and returns to the row address associated with the start of the clear operation, i.e., the stored starting row address RXADD_st, the access count value XCount associated with the refresh row address has been cleared during the first refresh operation and no longer needs to be cleared while refresh operations continue.

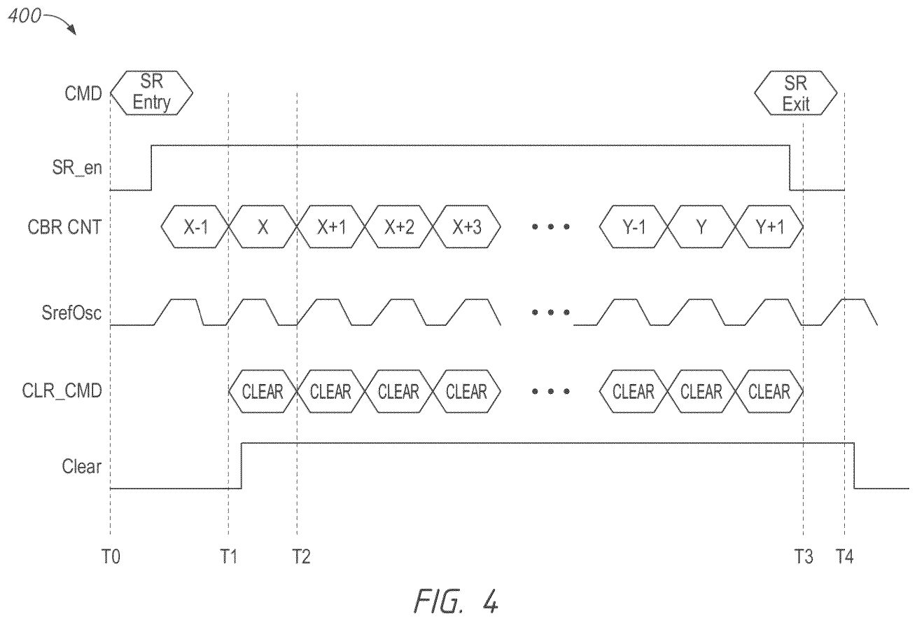

FIG. 4 is a timing chart of clear operations according to some embodiments of the present disclosure. The time chart 400 may, in some embodiments, represent the operation of one or more of the apparatuses and systems described herein. For example, the timing chart may represent the operation of a counter reset detector circuit 130 of FIG. 1, 216 of FIG. 2, and/or 300 of FIG. 3 (e.g., which may be implemented on the memory devices 100 of FIG. 1 and/or 200 of FIG. 2).

At an initial time T0, the memory device may enter a self-refresh mode responsive to a self-refresh mode entry command received by the memory device. The memory device may enter the self-refresh mode responsive to an external or an internal command CMD. For example, the self-refresh logic circuit (e.g., 228 of FIG. 2) may produce an internal self-refresh command responsive to a standby command from a controller. At TO, a self-refresh enable signal SR_en and a self-refresh oscillator signal SrefOsc are also sent by the self-refresh logic circuit (e.g., 228 of FIG. 2) to the counter reset detector circuit (e.g., 130 of FIG. 1, 242 of FIG. 2, and/or 300 of FIG. 3) and a refresh state control circuit (e.g., 236 of FIG. 2). Responsive to the self-refresh enable signal SR_en being enabled and the self-refresh oscillator signal SrefOsc, the refresh state control circuit will refresh a row address associated with the count stored in the refresh count CBR CNT.

At a first time T1, responsive to a transition of the self-refresh enable signal SR_en and the self-refresh oscillator signal SrefOsc, the refresh count CBR CNT will increment and the counter reset detector circuit (e.g., 130 of FIG. 1, 242 of FIG. 2, and/or 300 of FIG. 3) may begin to provide a clear signal Clear to begin clear operations. For example, responsive to a transition of the self-refresh enable signal from inactive to active and remaining active for a number of cycles of the self-refresh oscillator signal SrefOsc, the counter reset detector circuit (e.g., 130 of FIG. 1, 242 of FIG. 2, and/or 300 of FIG. 3) may issue a clear signal Clear, or set a clear flag, to an aggressor detector circuit (e.g., 232 of FIG. 2) to clear or reset an access count value XCount from counter memory cells (e.g., 126 of FIG. 1 and/or 252 of FIG. 2) associated with the row address being refreshed. In some embodiments, the counter reset detector circuit (e.g., 130 of FIG. 1, 242 of FIG. 2, and/or 300 of FIG. 3) may set a clear flag Clear after detecting the self-refresh enable signal SR_en as active for two consecutive cycles of the self-refresh oscillator signal SrefOsc. For example, the counter reset detector circuit (e.g., 130 of FIG. 1, 242 of FIG. 2, and/or 300 of FIG. 3) may set a clear flag Clear after detecting the self-refresh enable signal SR_en as high for two consecutive cycles of the self-refresh oscillator signal SrefOsc. It should be noted that the access count XCount associated with the first row address to be refreshed during the self-refresh operation is not cleared because the clear flag Clear is enabled after the first row address has been refreshed.

At a time T2, responsive to the memory device continuing to be in self-refresh mode, the refresh count CBR CNT may increment so that the next row address may be refreshed and the self-refresh oscillator signal SrefOsc may transition. The counter reset detector circuit (e.g., 130 of FIG. 1, 242 of FIG. 2, and/or 300 of FIG. 3) may issue a second clear command CLR_CMD and keep the clear flag Clear in an active state to clear or reset the access count value XCount in the counter memory cells (e.g., 126 of FIG. 1 and/or 252 of FIG. 2) associated with the next row address being refreshed. For example, the aggressor detector circuit (e.g., 232 of FIG. 2) may receive the clear flag Clear from the counter reset detector circuit (e.g., 130 of FIG. 1, 242 of FIG. 2, and/or 300 of FIG. 3) and in response, clear or reset the access count value XCount. During the self-refresh operation, the self-refresh oscillator SrefOsc will remain active and the refresh count CBR CNT will continue to increment responsive to the self-refresh oscillator signal SrefOsc. With each increment of the refresh count CBR CNT, a next row address may be refreshed and the associated access count XCount will be cleared.

At a time later, at time T3, the memory device may exit the self-refresh mode and the self-refresh enable signal SR_en may be disabled, for example by transitioning from high to low. Responsive to this transition, the self-refresh oscillator signal SrefOsc may be deactivated and the counter reset detector circuit (e.g., 130 of FIG. 1, 242 of FIG. 2, and/or 300 of FIG. 3) disable the clear flag Clear issued to the aggressor detector circuit. In some embodiments, the counter reset detector circuit (e.g., 130 of FIG. 1, 242 of FIG. 2, and/or 300 of FIG. 3) may monitor the self-refresh enable signal SR_en and if the counter reset detector circuit (e.g., 130 of FIG. 1, 242 of FIG. 2, and/or 300 of FIG. 3) detects a transition, for example from active to inactive, and the state of the self-refresh enable signal SR_en does not transition again for two consecutive cycles of the self-refresh oscillator signal SrefOsc, at a time T4, the counter reset detector circuit (e.g., 130 of FIG. 1, 242 of FIG. 2, and/or 300 of FIG. 3) will disable the clear flag Clear. For example, if the self-refresh enable signal SR_en is disabled or transitions from high to low and stays low for two consecutive cycles of the self-refresh oscillator signal SrefOsc, the counter reset detector circuit (e.g., 130 of FIG. 1, 242 of FIG. 2, and/or 300 of FIG. 3) will disable the clear flag Clear, at time T4.

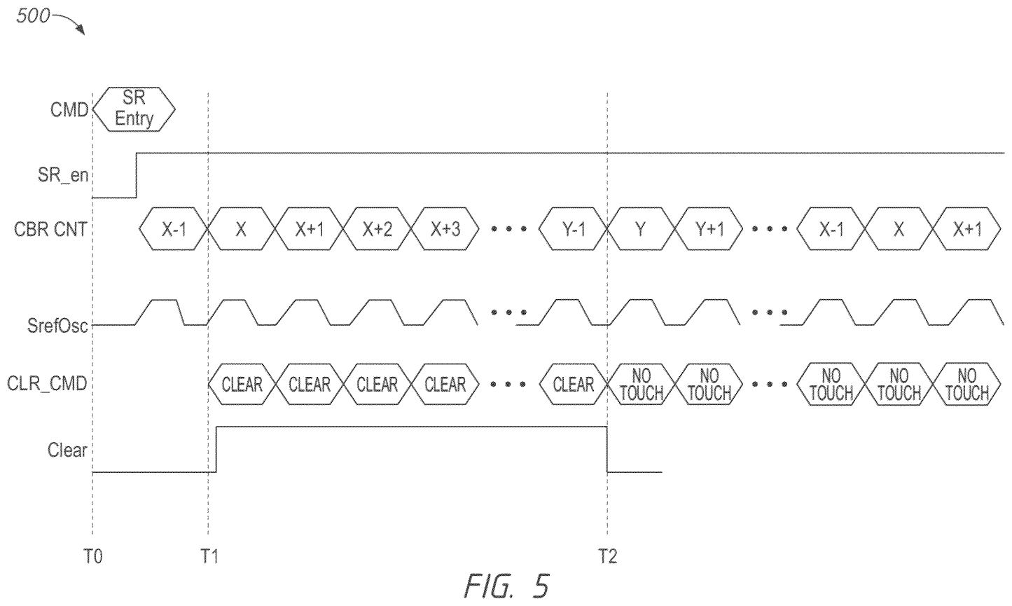

FIG. 5 is a timing chart of clear operations where the refresh address wraps back around to an initial value according to some embodiments of the present disclosure. The time chart 500 may, in some embodiments, represent the operation of one or more of the apparatuses and systems described herein. For example, the timing chart may represent the operation of a counter reset detector circuit 130 of FIG. 1, 216 of FIG. 2, and/or 300 of FIG. 3 (e.g., which may be implemented on the memory devices 100 of FIG. 1 and/or 200 of FIG. 2). The timing chart 500 may represent the operation of the counter reset detector during a self-refresh period that continues for enough time that all of the row addresses are refreshed and the self-refresh operation starts over with the first row address that was refreshed at the beginning of the self-refresh period.

At an initial time T0, the memory device may enter a self-refresh mode responsive to a self-refresh mode entry command received by the memory device. The memory device may enter the self-refresh mode responsive to an external or an internal command CMD. For example, the self-refresh logic circuit (e.g., 228 of FIG. 2) may produce an internal self-refresh command responsive to a standby command from a controller. At TO, a self-refresh enable signal SR_en and a self-refresh oscillator signal SrefOsc are also sent by the self-refresh logic circuit (e.g., 228 of FIG. 2) to the counter reset detector circuit (e.g., 130 of FIG. 1, 242 of FIG. 2, and/or 300 of FIG. 3) and a refresh state control circuit (e.g., 236 of FIG. 2). Responsive to the self-refresh enable signal SR_en being enabled and the self-refresh oscillator signal SrefOsc, the refresh state control circuit will refresh a row address associated with the count stored in the refresh count CBR CNT.

At a first time T1, responsive to a transition of the self-refresh enable signal SR_en and the self-refresh oscillator signal SrefOsc, the refresh count CBR CNT will increment and the counter reset detector circuit (e.g., 130 of FIG. 1, 242 of FIG. 2, and/or 300 of FIG. 3) may enable a clear flag Clear to begin clear operations. For example, responsive to a transition of the self-refresh enable signal from inactive to active and remaining active for a number of cycles of the self-refresh oscillator signal SrefOsc, the counter reset detector circuit (e.g., 130 of FIG. 1, 242 of FIG. 2, and/or 300 of FIG. 3) may issue a clear signal Clear, or set the clear flag Clear to high, to an aggressor detector circuit (e.g., 232 of FIG. 2) to clear or reset an access count value XCount from counter memory cells (e.g., 126 of FIG. 1 and/or 252 of FIG. 2) associated with the row address being refreshed. In some embodiments, the counter reset detector circuit (e.g., 130 of FIG. 1, 242 of FIG. 2, and/or 300 of FIG. 3) may enable a clear flag Clear after detecting the self-refresh enable signal SR_en as active for two consecutive cycles of the self-refresh oscillator signal SrefOsc. For example, the counter reset detector circuit (e.g., 130 of FIG. 1, 242 of FIG. 2, and/or 300 of FIG. 3) may enable a clear flag Clear after detecting the self-refresh enable signal SR_en as high for two consecutive cycles of the self-refresh oscillator signal SrefOsc.

At a later time T2, the refresh counter CBR CNT may cycle back to indicate the same address as was refreshed when the clear flag Clear was enabled. In other words, the self-refresh operation has refreshed all of the row addresses and started over. The count associated with the address refreshed when the clear flag Clear was enabled and thus the first row address to have its access count XCount cleared is depicted as “X” in FIG. 5. The counter reset detector circuit (e.g., 130 of FIG. 1, 242 of FIG. 2, and/or 300 of FIG. 3) may store the row address associated with the address refreshed when the clear flag Clear is enabled and compare that address with each new address as the refresh count CBR CNT increments. For example, the counter reset detector circuit (e.g., 130 of FIG. 1, 242 of FIG. 2, and/or 300 of FIG. 3) may include a starting address latch (e.g., 320 of FIG. 3) to store the first row address to have its access count XCount cleared and a comparator (e.g., 324 of FIG. 3) to compare the current row address with the stored starting row address. If they are equal, the counter reset detector circuit (e.g., 130 of FIG. 1, 242 of FIG. 2, and/or 300 of FIG. 3) may disable the clear flag Clear because all of the access counts XCount associated with all of the row addresses have been cleared or reset.

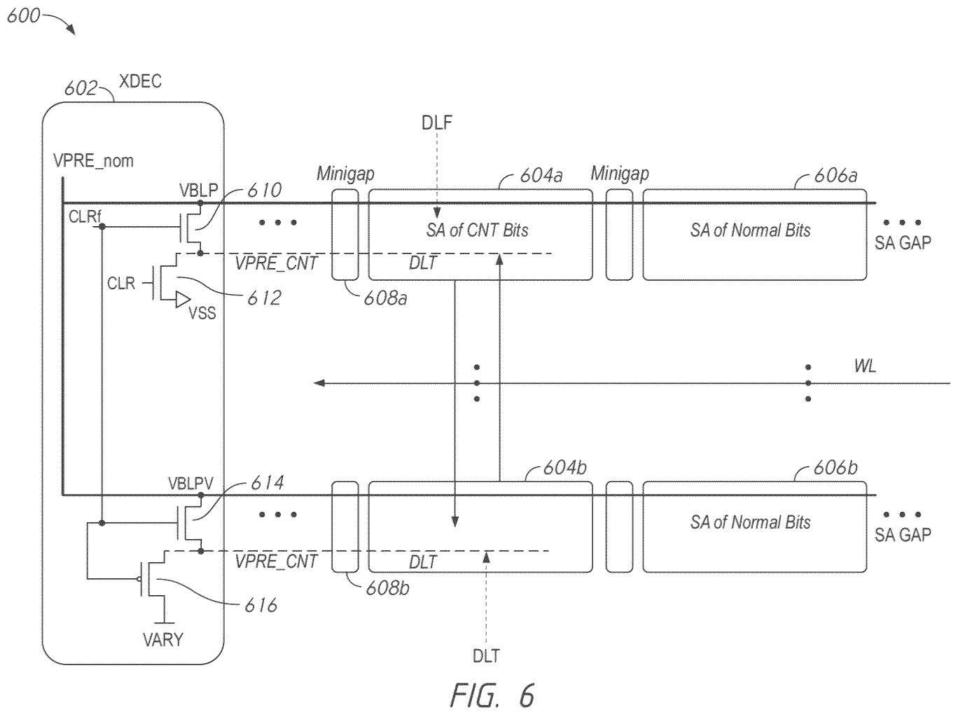

FIG. 6 is a block diagram according to some embodiments of the present disclosure. Circuit 600 may, in some embodiments, implement a portion of a memory device such as 100 of FIG. 1. The circuit 600 shows certain components and signals which are used in memory operations. The circuit 600 includes a row decoder 602 which may, in some embodiments, implement the row decoder 108 of FIG. 1 and/or 208 of FIG. 2. Also shown in FIG. 6 are a plurality of sense amplifiers (SA) 604 which may, in some embodiments, be included on a memory array such as 118 of FIG. 1.

Row decoder 602 (e.g., 108 of FIG. 1 and/or 208 of FIG. 2) includes logic to clear access count values XCount associated with word lines WL by driving a reset value on to the sense amplifiers (SA) for the access count values XCount using the pre-charge lines of the sense amplifiers. The reset value may be any value, such as 0. The access count values XCount may be coupled to sense amplifiers reserved for counter memory cells (e.g., 126 of FIG. 1 and/or 252 of FIG. 2) shown in FIG. 6 as SA of CNT bits 604a and 604b. The logic of the row decoder 602 may include a first N-type transistor 610 coupled to the sense amplifiers of the counter bits 604a and the sense amplifiers of the bits not used for count values, or normal bits, 606a for a plurality of word lines WL via a transmission line VBLP. The first N-type transistor may also be coupled to a second transmission line VPRE_CNT. The second transmission line VPRE_CNT may extend to the sense amplifiers of the counter bits 604a but not to the sense amplifiers of the normal bits 606a. The gate of the first N-type transistor 610 may be coupled to a gate of a second N-type transistor 614. The second N-type transistor 614 may be similarly coupled to an adjacent plurality of sense amplifiers 604b and 606b. For example, the second N-type transistor is coupled to a second plurality of sense amplifiers of counter bits 604b and a second plurality of sense amplifiers of normal bits 606b. The transmission line VBLP may be coupled to all sets of sense amplifiers 604a-b and 606a-b and coupled to a voltage source VPRE_nom. The second N-type transistor 614 may be coupled to the transmission line VPRE_CNT that extends to the sense amplifiers of the counter bits 604b but not to the sense amplifiers of the normal bits 606b. The first N-type transistor may be coupled to a third N-type transistor 612 that is coupled to a voltage source VSS and coupled to the clear signal CLR at its gate. The second N-type transistor 614 may be coupled to a first P-type transistor 616 that is coupled to a voltage source VARY. The gates of the first and second N-type transistors 610/614 may both be coupled to the gate of the first P-type transistor 616 and coupled to the inverse of the clear signal CLRf.

In some embodiments, the counter memory cells (e.g., 126 of FIG. 1 and/or 252 of FIG. 2) may be reset or cleared by writing a reset value to the cells. The reset value may be an initial value, such as 0. The reset value may be written to the counter memory cells (e.g., 126 of FIG. 1 and/or 252 of FIG. 2) via a write operation. A counter reset detector circuit (e.g., 130 of FIG. 1, 242 of FIG. 2, and/or 300 of FIG. 3) may initiate the write operation by enabling a clear flag Clear. An aggressor detector circuit (e.g., 232 of FIG. 2) may perform the write operation responsive to the clear flag Clear being enabled. In some embodiments, using the pre-charge level of the sense amplifiers for the access count values to drive a reset value on to the counter memory cells may result in a faster clearing operation than using a write operation due to the steps required to perform the write operation.

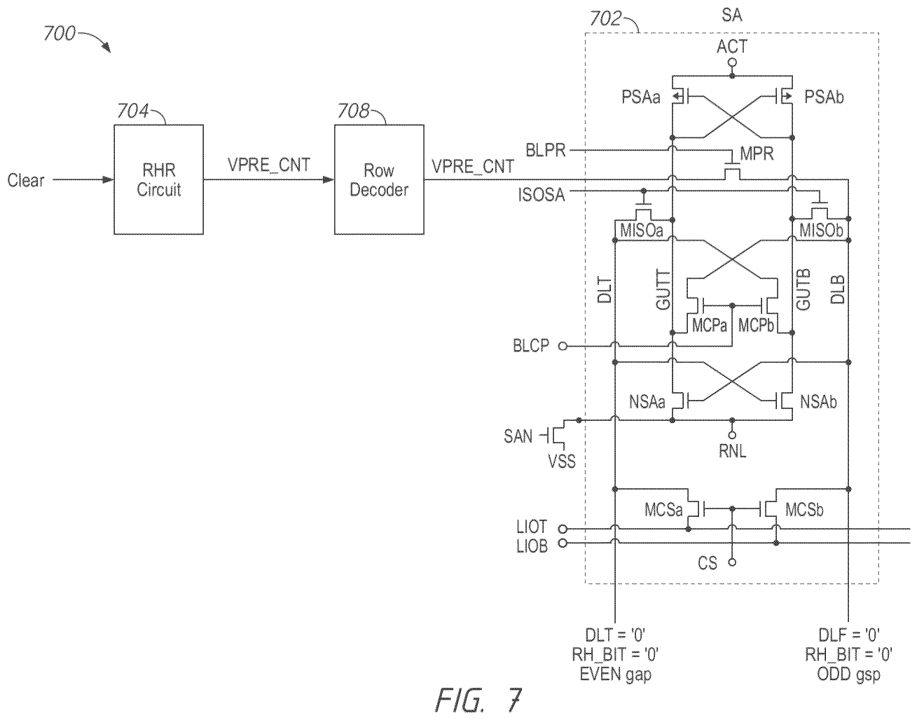

FIG. 7 is a block diagram of according to some embodiments of the present disclosure. Circuit 700 may, in some embodiments, implement a portion of a memory device such as 100 of FIG. 1. The circuit 700 shows certain components and signals which are used in memory operations. The circuit 700 includes an RHR circuit 704 which may, in some embodiments, implement the aggressor detector circuit 232 of FIG. 2. The circuit 700 includes a row decoder 708 which may, in some embodiments, implement row decoder 108 of Figure and/or 208 of FIG. 2. Also shown in FIG. 7 is a sense amplifier (SA) 702 which may, in some embodiments, be an implementation of the sense amplifiers of the counter bits 604a-b of FIG. 6. It should be noted that the sense amplifier 702 is an example embodiment of a sense amplifier and that sense amplifiers with other configurations may be used with the present disclosure.

Sense amplifier 702 may be coupled to a first digit line DLT, which is coupled to the accessed memory cell, and a second digit line DLB. The second digit line DLB may be used as a reference. The use of complimentary digit lines may be useful for differentiating between different voltages (e.g., by comparing the complimentary values). Sense amplifiers may be coupled between a pair of adjacent word lines, such as WL of FIG. 6, with the two digit lines coupled to a respective memory cell of the two word lines. During a clear operation, a reset value VPRE_CNT may be driven on to the second digit line DLB. The reset value VPRE_CNT may be issued from the RHR circuit 704 responsive to a clear flag Clear being enabled. The clear flag Clear may be issued from a counter reset detector circuit (e.g., 130 of FIG. 1, 242 of FIG. 2, and/or 300 of FIG. 3).

In some embodiments, responsive to the clear flag Clear, the RHR circuit 704 may drive a high signal, or a “1”, on to the second digit line DLB. Responsive to the “1” driven on to the second digit line DLB, the first digit line DLT will be driven to “0”. Thus, the word lines WL coupled to the first digit line DLT will have a “0” written to them. As depicted in FIG. 6, the reset signal VPRE_CNT extends to the sense amplifiers of the counter bits 604a/b of FIG. 6 and not to the sense amplifiers of the normal bits 606a/b. Thus, the clear signal Clear operates on the counter bits (e.g., 126 of FIG. 1 and/or 252 of FIG. 2) during a clear operation.

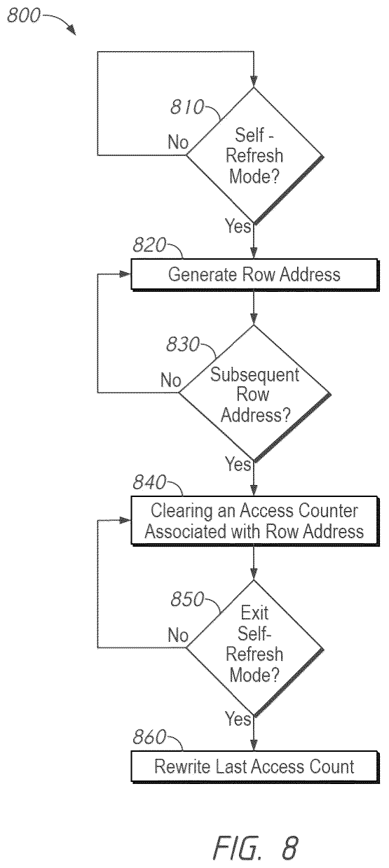

FIG. 8 is a flow chart of a method of clearing access count values during a self-refresh mode according to some embodiments of the present disclosure. The method 800 may, in some embodiments, be implemented by one or more apparatuses and/or systems described herein. For example, the method 800 may be implemented by the memory device 100 of FIG. 1 and/or 200 of FIG. 2 using counter reset detector circuits such as 130 of FIG. 1, 242 of FIG. 2, and/or 300 of FIG. 3.

The method 800 begins with box 810 which describes checking to see whether the memory device (e.g., 100 of FIG. 1 and/or 200 of FIG. 2) is in self-refresh mode. If the memory device (e.g., 100 of FIG. 1 and/or 200 of FIG. 2) is not in self-refresh mode, the device will continue to check periodically. If the memory device is in self-refresh mode, for example responsive to the memory device entering an IDLE state, the method 800 will continue to box 820.

Box 820 describes generating a row address. For example, responsive to a self-refresh oscillator signal (e.g., SrefOsc of FIGS. 2-4), a refresh control circuit (116 of FIG. 1 and/or 216 of FIG. 2) may refresh a row address. The row address may be a refresh row address RXADD produced by, in some embodiments, a refresh address generator (e.g., 238 of FIG. 2) included in the refresh control circuit (e.g., 116 of FIG. 1 and/or 216 of FIG. 2). The refresh address generator (e.g., 238 of FIG. 2) may generate the refresh address RXADD responsive to an internal refresh command IREF issued from a refresh state control circuit (e.g., 236 of FIG. 2) also included in the refresh control circuit (e.g., 116 of FIG. 1 and/or 216 of FIG. 2). After the refresh row address is refreshed, the method 800 will continue to box 830.

Box 830 describes checking whether the refresh row address has incremented. If the refresh row address has not incremented, the memory device (e.g., 100 of FIG. 1 and/or 200 of FIG. 2) will return to box 820 of the method 800 and generate a refresh row address. If the refresh row address has incremented, or in other words the memory device (e.g., 100 of FIG. 1 and/or 200 of FIG. 2) is refreshing a subsequent row associated with a subsequent refresh row address, for example a second row associated with a second refresh row address, the method 800 will continue to box 840.

Box 840 describes clearing an access counter associated with a row address. For example, the counter memory cells (e.g., 126 of FIG. 1 and/or 252 of FIG. 2) associated with the row address may be cleared, or reset. The row address may be a refresh row address RXADD generated by the refresh address generator (e.g., 238 of FIG. 2) that is being refreshed while the memory device (e.g., 100 of FIG. 1 and/or 200 of FIG. 2) is in a self-refresh mode. In some embodiments, the refresh row address RXADD may be a subsequent refresh row address to be refreshed during the self-refresh mode. For example, the clear operation may begin after the first row address is refreshed and clear an access count XCount from the counter memory cells (e.g., 126 of FIG. 1 and/or 252 of FIG. 2) of the second row address to be refreshed. In some embodiments, the clear operation may be performed by a counter reset detector circuit (e.g., 130 of FIG. 1, 242 of FIG. 2, and/or 300 of FIG. 3) included in the refresh control circuit (e.g., 116 of FIG. 1 and/or 216 of FIG. 2). After clearing the counter memory cells (e.g., 126 of FIG. 1 and/or 252 of FIG. 2) of the subsequent row address to be refreshed, the method 800 may continue to box 850.

Box 850 describes checking whether the memory device (e.g., 100 of FIG. 1 and/or 200 of FIG. 2) has exited the self-refresh mode. For example, whether the memory device (e.g., 100 of FIG. 1 and/or 200 of FIG. 2) may be indicated by the self-refresh enable signal SR_en of FIGS. 2-4. If the memory device (e.g., 100 of FIG. 1 and/or 200 of FIG. 2) has not exited the self-refresh mode, in other words if the memory device remains in the self-refresh mode, the counter reset detector circuit (e.g., 130 of FIG. 1, 242 of FIG. 2, and/or 300 of FIG. 3) will clear the access count XCount associated with the refresh row address RXADD generated by the refresh address generator (e.g., 238 of FIG. 2). If the memory device (e.g., 100 of FIG. 1 and/or 200 of FIG. 2) has exited self-refresh mode, as indicated for example by the self-refresh enable signal SR_en, the method 800 will continue to box 860.

Box 860 describes rewriting the last access count. For example, the counter reset detector circuit (e.g., 130 of FIG. 1, 242 of FIG. 2, and/or 300 of FIG. 3) may store the access count value XCount for each refresh address that is cleared until the next refresh address is refreshed. When the memory device (e.g., 100 of FIG. 1 and/or 200 of FIG. 2) exits the self-refresh mode, the counter reset detector circuit (e.g., 130 of FIG. 1, 242 of FIG. 2, and/or 300 of FIG. 3) will write the access count value XCount back to the counter memory cells (e.g., 126 of FIG. 1 and/or 252 of FIG. 2) associated with the last refresh row address RXADD. In some embodiments, the counter reset detector circuit (e.g., 130 of FIG. 1, 242 of FIG. 2, and/or 300 of FIG. 3) will store the access count value XCount of the last refresh row address in a latch circuit such as 322 of FIG. 3.

In some embodiments, the counter reset detector circuit (130 of FIG. 1, 242 of FIG. 2, and/or 300 of FIG. 3) may stop clearing the access count values XCount before the memory device (e.g., 100 of FIG. 1 and/or 200 of FIG. 2) exits the self-refresh mode. The counter reset detector circuit (130 of FIG. 1, 242 of FIG. 2, and/or 300 of FIG. 3) may include a starting address latch, such as 320 of FIG. 3, that stores the refresh row address RXADD associated with the first row address for which the access count value XCount was cleared, or reset. If a refresh row address RXADD received by the counter reset detector circuit (e.g., 130 of FIG. 1, 242 of FIG. 2, and/or 300 of FIG. 3) matches the refresh row address stored in the starting address latch (e.g., 320 of FIG. 3), the counter reset detector circuit (e.g., 130 of FIG. 1, 242 of FIG. 2, and/or 300 of FIG. 3) will stop clearing access count values XCount. This is because the memory device (e.g., 100 of FIG. 1 and/or 200 of FIG. 2) has been in the self-refresh mode long enough such that all of the row addresses have been refreshed and thus, all of the access count values XCount have been cleared, or reset.

In some embodiments, the counter reset detector circuit (e.g., 130 of FIG. 1, 242 of FIG. 2, and/or 300 of FIG. 3) may include a comparator circuit (e.g., 324 of FIG. 3) that compares the current refresh row address RXADD to the row address stored in the starting address latch (e.g., 320 of FIG. 3). If the current refresh row address RXADD is the same as the row address stored in the starting address latch (e.g., 320 of FIG. 3), then the counter reset detector circuit (e.g., 130 of FIG. 1, 242 of FIG. 2, and/or 300 of FIG. 3) may rewrite the last access count as described in box 860 and stop clearing the access count values XCount from the counter memory cells (e.g., 126 of FIG. 1 and/or 252 of FIG. 2) even though the memory device (e.g., 100 of FIG. 1 and/or 200 of FIG. 2) remains in the self-refresh mode.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array comprising a plurality of word lines each coupled to a plurality of memory cells and one or more counter memory cells configured to store a respective access count value; and
a refresh control circuit comprising:
a refresh state control circuit configured to refresh the plurality of memory cells coupled to a word line of the plurality of word lines associated with a respective row address responsive to a self-refresh mode being enabled;
a counter reset detector circuit configured to enable a clear flag responsive to the self-refresh mode being enabled; and
an aggressor detector circuit configured to clear the access count value associated with the row address associated with the refreshed plurality of memory cells responsive to the clear flag being enabled.

2. The apparatus of claim 1, wherein the counter reset detector circuit is further configured to store a starting row address.

3. The apparatus of claim 2, wherein the counter reset detector circuit further comprises a comparator configured to compare the stored starting row address with a current row address associated with the plurality of memory cells being refreshed and wherein the counter reset detector circuit is further configured to disable the clear flag responsive to the stored starting row address being the same as the current row address associated with the plurality of memory cells being refreshed.

4. The apparatus of claim 2, wherein the starting row address is the row address associated with the plurality of memory cells refreshed during a second refresh operation.

5. The apparatus of claim 1, wherein the aggressor detector circuit is further configured to clear the access count value by writing a zero over the access count value associated with the row address associated with the plurality of memory cells being refreshed.

6. The apparatus of claim 1, wherein the aggressor detector circuit is further configured to clear the access count value associated with the row address associated with the refreshed plurality of memory cells by driving a pre-charge value on to a sense amplifier associated with the access count value.

7. The apparatus of claim 6, wherein clearing the access count value by driving the pre-charge value on to the sense amplifier associated with the access count value is faster than clearing the access count value by performing a write operation.

8. The apparatus of claim 1, wherein the counter reset detector circuit is further configured to store a last access count value that is the access count value associated with a current row address being refreshed responsive to the self-refresh mode being enabled.

9. The apparatus of claim 8, wherein the counter reset detector circuit is further configured to write the stored last access count value back to the plurality of memory cells associated with the row address last refreshed responsive to the self-refresh mode being disabled.

10. The apparatus of claim 1, wherein the counter reset detector circuit is further configured to disable the clear flag responsive to the self-refresh mode being disabled.

11. An apparatus comprising:
an access count latch configured to store an access count associated with a row address associated with a plurality of memory cells being refreshed during a self-refresh operation responsive to a self-refresh enable signal being enabled, wherein the stored access count is updated to the access count associated with a next row address associated with a next plurality of memory cells being refreshed responsive to a transition of a self-refresh oscillator signal; and
a counter reset detector logic circuit configured to enable a clear flag responsive to the self-refresh enable signal being enabled, wherein the clear flag is configured to clear the access count associated with the row address associated with the plurality of memory cells being refreshed and wherein, responsive to the self-refresh enable signal being disabled, the counter reset detector logic circuit is further configured to rewrite the stored access count back to counter memory cells associated with a current row address associated with a current plurality of memory cells being refreshed.

12. The apparatus of claim 11, further comprising:
a first latch configured to receive the row address associated with the plurality of memory cells being refreshed during the self-refresh operation and store a starting row address responsive to the self-refresh enable signal being enabled; and
a comparator circuit configured to compare the stored starting row address with the current row address associated with the current plurality of memory cells being refreshed.

13. The apparatus of claim 12, wherein the stored starting row address is the row address received on a second transition of the self-refresh oscillator signal.

14. The apparatus of claim 12, wherein the counter reset detector logic circuit is further configured to disable the clear flag if the starting row address is the same as the current row address.

15. A method comprising:
entering a self-refresh mode of a memory device;
generating a first row address associated with a plurality of memory cells to be refreshed;
generating a subsequent row address associated with a subsequent plurality of memory cells to be refreshed; and
clearing an access count value associated with the subsequent row address.

16. The method of claim 15, further comprising:
exiting the self-refresh mode; and
rewriting an access count value associated with a last refreshed row address associated with a last refreshed plurality of memory cells.

17. The method of claim 15, further comprising:
storing the subsequent row address associated with the subsequent plurality of memory cells to be refreshed;
iterating the subsequent row address to generate a current row address associated with a current plurality of memory cells to be refreshed;
comparing the current row address associated with the current plurality of memory cells to be refreshed with the stored subsequent row address; and
discontinuing clear operations if the current row address matches the stored subsequent row address.

18. The method of claim 15, wherein clearing the access count value associated with the subsequent row address comprises writing a reset value to a counter memory cell associated with the subsequent row address.

19. The method of claim 15, wherein clearing the access count value associated with the subsequent row address comprises driving a pre-charge value on to a sense amplifier associated with the subsequent row address.

20. The method of claim 15, further comprising:
enabling a clear flag responsive to the generating of the subsequent row address associated with the subsequent plurality of memory cells to be refreshed.

21. The method of claim 15, wherein the subsequent row address is a second row address.
